(19) United States
(12) Patent Application Publication
(10) Pub. No.: US 2026/0293309 A1
(43) Pub. Date: Sep. 24, 2026

(54) ELECTRONIC DEVICE

(71) Applicant: NuFlare Technology, Inc., Yokohama-shi (JP)

(72) Inventors: Kei OBARA, Kawasaki (JP); Kazuyuki HIGASHI, Yokohama (JP); Kazumichi TSUMURA, Shinagawa (JP); Hideo INOUE, Miura (JP)

(73) Assignee: NuFlare Technology, Inc., Yokohama-shi (JP)

(21) Appl. No.: 19/415,935

(22) Filed: Dec. 11, 2025

(30) Foreign Application Priority Data
Mar. 21, 2025 (JP) 2025-046230

(51) Int. Cl. H10D 86/40

(52) U.S. Cl. CPC H10D 86/441

(57) ABSTRACT

An electronic device includes a substrate, an electrode extending toward a side opposite to the substrate in a first direction, and a wiring portion provided between the substrate and the electrode in the first direction. The wiring portion includes an insulating layer having a first face located on the side opposite to the substrate in the first direction, a wiring layer provided in the insulating layer, and an opening portion reaching the wiring layer from the first face of the insulating layer. The opening portion includes a first portion extending in a second direction orthogonal to the first direction, and a second portion protruding from the first portion in a direction orthogonal to the first direction and crossing the second direction. The electrode being provided on the first face and is connected to the wiring layer at the first portion and the second portion of the opening portion.

### CROSS-REFERENCE TO RELATED APPLICATION

This application is based upon and claims the benefit of priority from Japanese Patent Application No. 2025-046230, filed on March 21, 2025; the entire contents of which are incorporated herein by reference.

### FIELD

Embodiments of the invention relate to an electronic device.

### BACKGROUND

A configuration is known in which an electrode provided on an insulating layer is connected to a wiring layer in the insulating layer, in an opening portion formed in the insulating layer.

### SUMMARY

Embodiments of the invention provide an electronic device in which the strength of connection between an electrode and a wiring layer can be increased.

According to an embodiment of the invention, an electronic device includes a substrate, an electrode extending toward a side opposite to the substrate in a first direction, and a wiring portion provided between the substrate and the electrode in the first direction, the wiring portion includes an insulating layer having a first face located on the side opposite to the substrate in the first direction, a wiring layer provided in the insulating layer, and an opening portion reaching the wiring layer from the first face of the insulating layer, the opening portion includes a first portion extending in a second direction orthogonal to the first direction, and a second portion protruding from the first portion in a direction orthogonal to the first direction and crossing the second direction, and the electrode is provided on the first face and is connected to the wiring layer at the first portion and the second portion of the opening portion.

### BRIEF DESCRIPTION OF THE DRAWINGS

FIG. 1 is a schematic plan view of an electronic device according to an embodiment;

FIG. 2 is a cross-sectional view taken along line A-A in FIG. 1; and

FIGS. 3A to 4B are schematic plan views showing modifications of an opening portion in the electronic device according to the embodiment.

### DETAILED DESCRIPTION

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

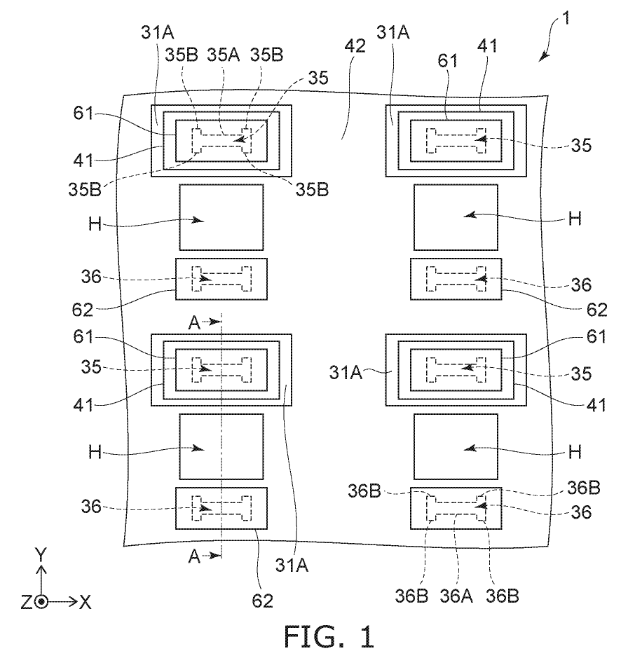

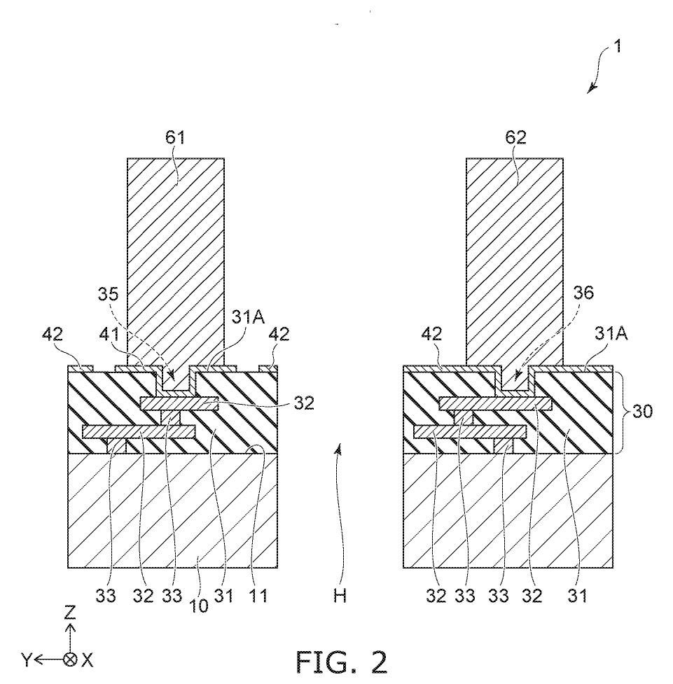

FIG. 1 is a schematic plan view of an electronic device 1 according to an embodiment. FIG. 2 is a cross-sectional view taken along line A-A in FIG. 1.

In this embodiment, the electronic device 1 includes a substrate 10, a wiring portion 30, a first electrode 61, a second electrode 62, a first conductive film 41, a second conductive film 42, and a through hole H. The through hole H penetrates the wiring portion 30 and the substrate 10 in a first direction Z. Two directions orthogonal to each other in a plane orthogonal to the first direction Z are defined as a second direction X and a third direction Y.

The substrate 10 is, for example, a silicon substrate. For example, a control element, such as a semiconductor transistor, is formed on a surface 11 side of the substrate 10.

The wiring portion 30 is provided on the surface 11 of the substrate 10. The wiring portion 30 is provided between the substrate 10 and the first electrode 61 and between the substrate 10 and the second electrode 62 in the first direction Z. The wiring portion 30 includes at least a wiring layer 32 in one layer. This embodiment illustrates an example in which the wiring portion 30 has a multilayer wiring structure including wiring layers 32 in multiple layers. The wiring portion 30 includes the wiring layer 32 and an insulating layer 31. The wiring layer 32 is provided in the insulating layer 31. In a case where wiring layers 32 in multiple layers are provided, the wiring portion 30 further includes a conductive via 33 connecting the wiring layers 32 in different layers to each other. The wiring layer 32 is electrically connected to the control element, such as a semiconductor transistor, formed on the substrate 10. As the material of the wiring layer 32 and the conductive via 33, for example, copper, aluminum, or tungsten can be used.

The insulating layer 31 has a first face 31A located on the side opposite to the surface 11 of the substrate 10 in the first direction Z. The insulating layer 31 includes a first opening portion 35 and a second opening portion 36 reaching the wiring layer 32 from the first face 31A. As the material of the insulating layer 31, for example, silicon oxide or silicon nitride can be used.

The first conductive film 41 and the second conductive film 42 are provided on the first face 31A of the insulating layer 31. The first conductive film 41 and the second conductive film 42 are separated from each other on the first face 31A of the insulating layer 31. As the material of the first conductive film 41 and the second conductive film 42, for example, TiN (titanium nitride) can be used.

The first conductive film 41 is also provided in the first opening portion 35 and is connected to the wiring layer 32 in the first opening portion 35. The first conductive film 41 provided on the first face 31A and the first conductive film 41 provided in the first opening portion 35 are continuous.

The second conductive film 42 is also provided in the second opening portion 36 and is connected to the wiring layer 32 in the second opening portion 36. The second conductive film 42 provided on the first face 31A and the second conductive film 42 provided in the second opening portion 36 are continuous.

The first electrode 61 and the second electrode 62 are provided on the first face 31A and extend toward the side opposite to the substrate 10 in the first direction Z. As the material of the first electrode 61 and the second electrode 62, for example, Au (gold) can be used.

The first conductive film 41 is provided between the insulating layer 31 and the first electrode 61 in the first opening portion 35. A part of the first electrode 61 is connected to the first conductive film 41 in the first opening portion 35. The first electrode 61 is electrically connected to the wiring layer 32 via the first conductive film 41.

The second conductive film 42 is provided between the insulating layer 31 and the second electrode 62 in the second opening portion 36. A part of the second electrode 62 is connected to the second conductive film 42 in the second opening portion 36. The second electrode 62 is electrically connected to the wiring layer 32 via the second conductive film 42.

A first system in which the wiring layer 32 and the first electrode 61 are electrically connected via the first conductive film 41 and a second system in which the wiring layer 32 and the second electrode 62 are electrically connected via the second conductive film 42 can be controlled independently of each other. To the first electrode 61 and the second electrode 62, different potentials can be applied. For example, it is possible to apply a positive potential to the first system and a ground potential to the second system to thereby generate an electric field between the first electrode 61 and the second electrode 62. This electric field can deflect, for example, a charged particle beam, such as an electron beam, passing between the first electrode 61 and the second electrode 62 and passing through the through hole H.

The electronic device 1 according to this embodiment can be used in, for example, an electron microscope for observing surfaces with an electron beam, an electron beam writer for writing fine patterns on masks or wafers, or an inspection apparatus for detecting defects by scanning a surface with an electron beam.

As shown in FIG. 1, the electronic device 1 according to this embodiment includes a plurality of through holes H, a plurality of first electrodes 61, and a plurality of second electrodes 62. The plurality of through holes H are arranged in the second direction X and the third direction Y. In plan view, each through hole H is located between the first electrode 61 and the second electrode 62. For example, in plan view, the first electrode 61 and the second electrode 62 are located with the through hole H interposed therebetween in the third direction Y. Corresponding to the plurality of first electrodes 61, a plurality of first conductive films 41 are disposed on the first face 31A of the insulating layer 31. On the first face 31A, the second conductive film 42 surrounds each first conductive film 41.

According to this embodiment, since the first electrode 61, the through hole H, and the second electrode 62 are arranged in the third direction Y, the widths of the first electrode 61 and the second electrode 62 in the third direction Y are restricted by the through hole H. According to this embodiment, in plan view, the widths of the first electrode 61 and the second electrode 62 in the third direction Y are smaller than the widths of the first electrode 61 and the second electrode 62 in the second direction X. In plan view, the first electrode 61 and the second electrode 62 are elongated in the second direction X.

The planar shape of the first opening portion 35 for connecting the first electrode 61 to the wiring layer 32 is also elongated in the second direction X to match the planar shape of the first electrode 61. That is, the first opening portion 35 includes a first portion 35A extending in the second direction X.

Similarly, the planar shape of the second opening portion 36 for connecting the second electrode 62 to the wiring layer 32 is also elongated in the second direction X to match the planar shape of the second electrode 62. That is, the second opening portion 36 includes a first portion 36A extending in the second direction X.

In order to allow the electric field between the first electrode 61 and the second electrode 62 to easily influence the charged particle beam, the length (height) of the first electrode 61 in the first direction Z is larger than the width of the first electrode 61 in the second direction X, and the length (height) of the second electrode 62 in the first direction Z is larger than the width of the second electrode 62 in the second direction X. Since the first electrode 61 and the second electrode 62 have a relatively high aspect ratio (the ratio of the height to the width) as described above, there is a concern that the strength of connection with the wiring layer 32 may be decreased and the connection may be lost during the process of manufacturing the electronic device 1. For example, the first electrode 61 and the second electrode 62 can be formed by plating, and the first electrode 61 and the second electrode 62 are likely to fall down during a subsequent wet process, such as cleaning.

According to this embodiment, in addition to the first portion 35A extending in the second direction X, the first opening portion 35 includes a second portion 35B protruding from the first portion 35A in a direction (the third direction Y in the example shown in FIG. 1) orthogonal to the first direction Z and crossing the second direction X. This can increase the strength of connection between the first electrode 61 and the wiring layer 32 in the first opening portion 35, and can make the first electrode 61 be less likely to fall down. According to this embodiment, since the number of corners of the first opening portion 35 is increased while an increase in the area of the first opening portion 35 in plan view is suppressed, the strength of connection between the first electrode 61 and the wiring layer 32 can be increased. The first electrode 61 is connected to the wiring layer 32 at the first portion 35A and the second portion 35B of the first opening portion 35.

Similarly, in addition to the first portion 36A extending in the second direction X, the second opening portion 36 includes a second portion 36B protruding from the first portion 36A in a direction (the third direction Y in the example shown in FIG. 1) orthogonal to the first direction Z and crossing the second direction X. This can increase the strength of connection between the second electrode 62 and the wiring layer 32 in the second opening portion 36, and can make the second electrode 62 be less likely to fall down. The second electrode 62 is connected to the wiring layer 32 at the first portion 36A and the second portion 36B of the second opening portion 36.

In order to further increase the strength of connection between the first electrode 61 and the wiring layer 32, the first opening portion 35 preferably includes a plurality of second portions 35B. Similarly, the second opening portion 36 preferably includes a plurality of second portions 36B. In the example shown in FIG. 1, the first opening portion 35 includes four second portions 35B located in the four corners of the first portion 35A, and the second opening portion 36 includes four second portions 36B located in the four corners of the first portion 36A.

In this embodiment, a plurality of second portions 35B protrude from the first portion 35A at each of both end portions of the first portion 35A in the second direction X, and a plurality of second portions 36B protrude from the first portion 36A at each of both end portions of the first portion 36A in the second direction X. Accordingly, the second portions 35B are symmetrically formed in the second direction X in which the first portion 35A extends and the second portions 36B are symmetrically formed in the second direction X in which the first portion 36A extends, and an imbalance in the strength of connection of the electrodes in the second direction X does not occur.

A plurality of second portions 35B protrude from each of the two outer edges of the first portion 35A extending in the second direction X, and a plurality of second portions 36B protrude from each of the two outer edges of the first portion 36A extending in the second direction X. Accordingly, an imbalance in the strength of connection of the electrodes in a direction (the third direction Y in this embodiment) crossing the second direction X does not occur.

The first conductive film 41 enhances adhesion between the first electrode 61 and the insulating layer 31. According to this embodiment, as shown in FIG. 1, the outer edge of the first electrode 61 is located inside the outer edge of the first conductive film 41 in plan view. The planar size of the first conductive film 41 is larger than the plane size of the first electrode 61. These can increase the area of connection between the first conductive film 41 and the first electrode 61 on the first face 31A of the insulating layer 31, and can increase the strength of connection between the first conductive film 41 and the first electrode 61.

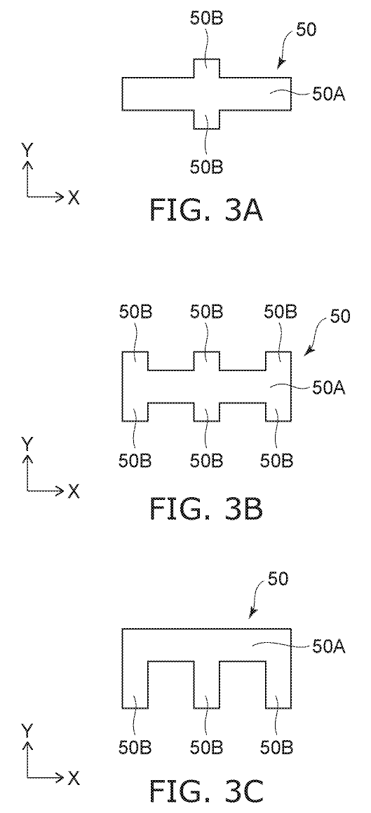

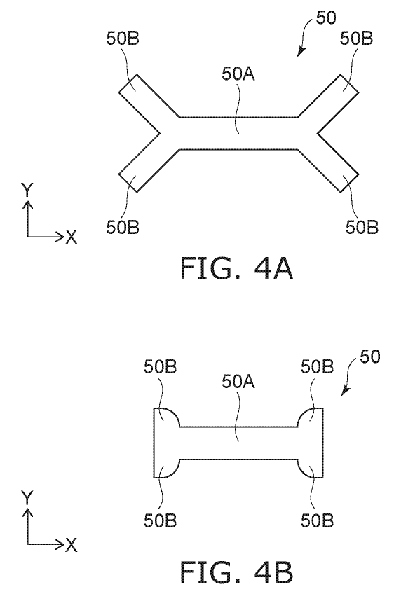

Modifications of the shape of the opening portions in the insulating layer 31 in plan view will be described below with reference to FIGS. 3A to 4B. An opening portion 50 shown in FIGS. 3A to 4B is applicable to both the first opening portion 35 and the second opening portion 36 described above.

The opening portion 50 shown in FIG. 3A includes a first portion 50A extending in the second direction X and two second portions 50B protruding from the first portion 50A in the third direction Y. The two second portions 50B are located at a central portion of the first portion 50A in the second direction X and protrude in opposite directions.

The opening portion 50 shown in FIG. 3B is a combination of the opening portion shown in FIG. 1 and the opening portion shown in FIG. 3A. The opening portion 50 shown in FIG. 3B includes the first portion 50A extending in the second direction X and six second portions 50B protruding from the first portion 50A in the third direction Y.

The opening portion 50 shown in FIG. 3C includes the first portion 50A extending in the second direction X and three second portions 50B protruding from the first portion 50A in the third direction Y. The three second portions 50B are located at both end portions and the central portion of the first portion 50A in the second direction X, and protrude in the same direction.

The opening portion 50 shown in FIG. 4A includes the first portion 50A extending in the second direction X and four second portions 50B. The four second portions 50B protrude in directions inclined with respect to the second direction X and the third direction Y. Of the four second portions 50B, two second portions 50B are located at one end portion of the first portion 50A in the second direction X, and the remaining two second portions 50B are located at the other end portion of the first portion 50A in the second direction X.

The opening portion 50 shown in FIG. 4B includes the first portion 50A extending in the second direction X and four second portions 50B protruding from the first portion 50A in the third direction Y. The outer edge of the second portions 50B has a curvature.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic device comprising:
a substrate;
an electrode extending toward a side opposite to the substrate in a first direction; and
a wiring portion provided between the substrate and the electrode in the first direction,
the wiring portion including an insulating layer having a first face located on the side opposite to the substrate in the first direction, a wiring layer provided in the insulating layer, and an opening portion reaching the wiring layer from the first face of the insulating layer,
the opening portion including a first portion extending in a second direction orthogonal to the first direction, and a second portion protruding from the first portion in a direction orthogonal to the first direction and crossing the second direction,
the electrode being provided on the first face and being connected to the wiring layer at the first portion and the second portion of the opening portion.

2. The electronic device according to claim 1, wherein
the opening portion includes a plurality of the second portions.

3. The electronic device according to claim 2, wherein
the plurality of second portions include a plurality of second portions protruding from the first portion at each of both end portions of the first portion in the second direction.

4. The electronic device according to claim 2, wherein
the plurality of second portions include a plurality of second portions protruding from each of two outer edges of the first portion, the two outer edges extending in the second direction.

5. The electronic device according to claim 1, further comprising:
a through hole penetrating the substrate and the wiring portion in the first direction.

6. The electronic device according to claim 5, wherein
the electrode includes a first electrode and a second electrode to which different potentials are applied, and
the through hole is located between the first electrode and the second electrode in plan view.

7. The electronic device according to claim 1, further comprising:
a conductive film provided between the insulating layer and the electrode in the opening portion.

8. The electronic device according to claim 7, wherein
an outer edge of the electrode is located inside an outer edge of the conductive film in plan view.

9. The electronic device according to claim 1, wherein
a length of the electrode in the first direction is larger than a width of the electrode in the second direction.
